(19) United States
(12) Patent Application Publication
(10) Pub. No.: US 2026/0354143 A1
(43) Pub. Date: Nov. 5, 2026

(54) RESPONSIVE LAYER FOR GAP FILL AND PLANARIZATION

(71) Applicant: Applied Materials, Inc., Santa Clara, CA (US)

(72) Inventors: KEVIN GU, Mountain View, CA (US); RUDY WOJTECKI, East Garrison, CA (US); ZHIYU HUANG, Sunnyvale, CA (US); PRASHANT KULSHRESHTHA, Sunnyvale, CA (US); ISHWAR SINGH, Sunnyvale, CA (US); SIVANANDHA KANAKASABAPATHY, Pleasanton, CA (US); CHING-YU CHANG, Hsinchu County (TW)

(21) Appl. No.: 19/196,721

(22) Filed: May 1, 2025

(51) Int. Cl. H10W 20/00; H10P 14/60; H10P 14/68

(52) U.S. Cl. CPC H10W 20/098; H10P 14/6336; H10P 14/668; H10P 14/683; H10W 20/095; H10W 20/096; H10W 20/097

(57) ABSTRACT

Embodiments described herein relate to a method that includes depositing a responsive layer over a patterned layer, where the responsive layer has a surface with a first flatness. In an embodiment, the method further includes treating the responsive layer with a stimulus, where the treated responsive layer is reflowed by the stimulus to obtain a second flatness along the surface that is flatter than the first flatness.

### BACKGROUND

### 1) Field

Embodiments relate to the field of semiconductor manufacturing and, in particular, apparatuses and methods for using a responsive layer for improved gap fill and planarization.

### 2) Description of Related Art

In semiconductor manufacturing, a first layer may be patterned (e.g., with etching processes or the like) and a second layer may be deposited over the patterned first layer. Depending on the material of the second layer and the deposition process, the second layer may fill gaps and/or openings in the patterned first layer as well as cover a top surface of the first layer. As the pitch of the patterns in layers continue to reduce, fully filling the openings so there are no voids becomes more challenging. Further, the deposition process may at least partially conform to the pattern of the first layer. As such, the top surface of the second layer may not be flat. That is, the top surface of the second layer may have peaks and valleys that align with the location of the openings through the first layer.

As manufacturing continues with the formation of additional layers, the undulating surface leads to manufacturing difficulties. For example, lithography processes may become more difficult due to a non-planar surface. This is particularly problematic for lithography processes (e.g., extreme ultraviolet (EUV) lithography) that rely on high numerical aperture (high-NA) lenses which have a small depth-of-focus.

### SUMMARY

Embodiments described herein relate to a method that includes depositing a responsive layer over a patterned layer, where the responsive layer has a surface with a first flatness. In an embodiment, the method further includes treating the responsive layer with a stimulus, where the treated responsive layer is reflowed by the stimulus to obtain a second flatness along the surface that is flatter than the first flatness.

Embodiments described herein relate to a method that includes depositing a fill layer over a patterned layer, where the fill layer has a first surface with a first flatness, and depositing a responsive layer over the fill layer, where the responsive layer has a second surface with a second flatness. In an embodiment, the method further includes treating the responsive layer with a stimulus, where the treated responsive layer is reflowed by the stimulus to obtain a third flatness along the second surface that is flatter than the second flatness.

Embodiments described herein relate to a method that includes patterning a first layer that is provided over a substrate, where the patterning forms an opening through the first layer. In an embodiment, the method further includes depositing a second layer over the first layer with a plasma enhanced chemical vapor deposition (PECVD) process, where the second layer includes a material that is reflowable in response to a stimulus. In an embodiment, the method further includes applying the stimulus to the second layer that results in the second layer being reflowed while the first layer remains substantially unchanged.

### BRIEF DESCRIPTION OF THE DRAWINGS

FIG. 1A is a cross-sectional illustration of a device with a patterned layer, in accordance with an embodiment.

FIG. 1B is a cross-sectional illustration of the device with a fill layer deposited over the patterned layer, in accordance with an embodiment.

FIG. 2A is a cross-sectional illustration of a device with a patterned layer, in accordance with an embodiment.

FIG. 2B is a cross-sectional illustration of the device with a responsive layer deposited over the patterned layer, in accordance with an embodiment.

FIG. 2C is a cross-sectional illustration of the device during a treatment of the fill layer that reflows the fill layer to provide a smoother top surface, in accordance with an embodiment.

FIG. 3A is a cross-sectional illustration of a device with a patterned layer, in accordance with an embodiment.

FIG. 3B is a cross-sectional illustration of the device with a fill layer deposited over the patterned layer, in accordance with an embodiment.

FIG. 3C is a cross-sectional illustration of the device after a responsive layer is deposited over the fill layer, in accordance with an embodiment.

FIG. 3D is a cross-sectional illustration of the device during a treatment of the responsive layer, in accordance with an embodiment.

FIG. 3E is a cross-sectional illustration of the device after the responsive layer is reflowed after the treatment to provide a smoother top surface, in accordance with an embodiment.

FIG. 4 is a flow diagram that depicts a process of forming a responsive layer that is reflowed to improve the flatness of the responsive layer, in accordance with an embodiment.

FIG. 5 is a flow diagram that depicts a process of forming a responsive layer over a fill layer, and where the responsive layer is reflowed to improve the flatness of the responsive layer, in accordance with an embodiment.

FIG. 6 illustrates a block diagram of an exemplary computer system that may be used in conjunction with a processing tool, in accordance with an embodiment.

### DETAILED DESCRIPTION

Embodiments described herein include apparatuses and methods for using a responsive layer for improved gap fill and planarization. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, advanced lithography processes, such as extreme ultraviolet (EUV) lithography, need highly planar surfaces due to the high numerical aperture (high-NA) lenses used for the lithographic exposure processes. Since the high-NA lenses have poor depth of focus, the photoresist material needs to have a highly uniform thickness. When the underlying surface is non-planar, the overlying photoresist layer will have a non-uniform thickness.

In some manufacturing process flows, a layer is deposited over an underlying patterned layer. Since the underlying patterned layer has openings, gaps, or the like, the overlying layer will at least partially conform to the pattern. This may result in the overlying layer having a surface that includes peaks and valleys. This non-planar surface causes manufacturing difficulties during subsequent processing.

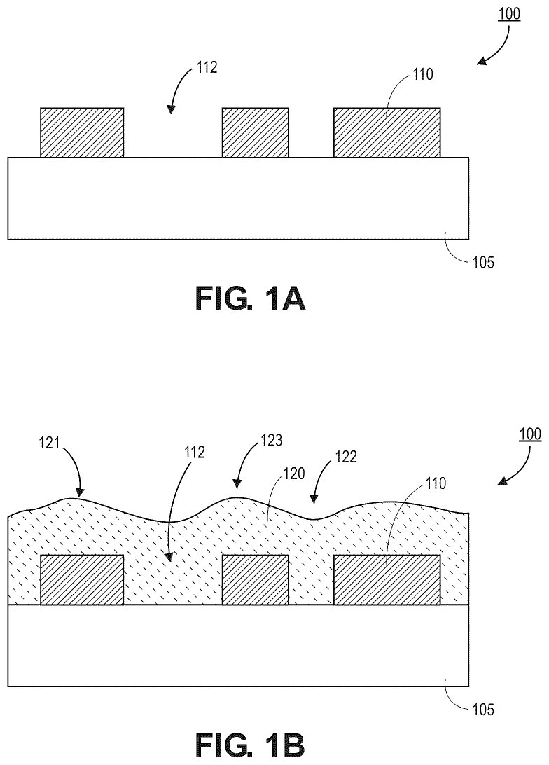

An example of a such an issue is shown in FIGS. 1A and 1B. As shown in FIG. 1A, a device 100 with a patterned layer 110 that is provided over a substrate 105 is shown. The patterned layer 110 may have one or more openings 112, recesses, gaps, or the like. For example, the opening 112 passes through a thickness of the patterned layer 110. In the illustration of FIG. 1A the openings 112 have non-uniform dimensions. Though, other devices 100 may include a patterned layer 110 with openings 112 that are substantially uniform. The openings 112 may define line/space patterns, hole patterns, and/or the like.

Referring now to FIG. 1B, a cross-sectional illustration of the device 100 after a fill layer 120 is deposited over the patterned layer 110 is shown. As shown, the fill layer 120 is deposited to a thickness that allows for the patterned layer 110 to be covered. The fill layer 120 may substantially fill the openings 112 through the patterned layer 110 and cover the top surface of the patterned layer 110.

A top surface 121 of the fill layer 120 may be non-planar. That is, the top surface 121 may comprise one or more peaks 123 and/or valleys 122. Due to the conformal nature of the deposition process used to deposit the fill layer 120, the valleys 122 may be aligned with the openings 112 through the patterned layer 110. In some instances, the deposition process may be a chemical vapor deposition (CVD) process.

As noted above, the presence of the peaks 123 and valleys 122 along the top surface 121 of the fill layer 120 increases manufacturing complexity in subsequently deposited and/or patterned layers. Accordingly, it is desirable to provide a fill layer 120 that has a substantially planar surface or a substantially flat surface. In this way subsequent manufacturing of the device 100 is simplified.

In some instances, a liquid based deposition process may be used to provide a smoother top surface 121 for the fill layer 120. For example, the fill layer 120 may be dispensed over the patterned layer 110 with a spin coating process. Since the fill layer 120 is deposited as a liquid, the fill layer 120 may minimize surface energy in order to provide a substantially flat surface. The liquid fill layer 120 may then be cured in order to provide a solid fill layer 120. However, such spin coating solutions may not be desirable. For example, the device 100 may need to be removed from a CVD chamber in order to implement the spin coating process. Additionally, material selection for spin coating compatible fill layers 120 may be limited.

Accordingly, embodiments disclosed herein use a modifiable responsive layer that is deposited over the patterned layer. The responsive layer may fill gaps and/or openings formed into and/or through the patterned layer. The responsive layer is formed from a material that is capable of “reflow” in response to a stimulus. As such, the responsive layer may be deposited with a suitable deposition process (e.g., chemical vapor deposition (CVD), plasma enhanced CVD (PECVD), or the like). Due to the topography of the patterned layer, the responsive layer may exhibit poor flatness, as is common with such deposition processes. Thereafter, a stimulus (e.g., thermal annealing, electromagnetic radiation, laser annealing, ion implantation, or chemical treatment) is applied to the responsive layer to initiate the reflow in order to produce a surface with improved flatness. Flatness of a surface may refer to a measure of a distance between a peak and valley on the surface. The measure of flatness may refer to the difference between a highest peak and a lowest valley of the surface, or the measure of flatness may refer to the difference between a peak and a nearest valley.

As used herein “reflow” may refer to several different processes. In one embodiment, reflow may refer to bringing a material above a glass transition temperature of the material or a melting point of the material. In this state, the material can flow (similar to a fluid). In other embodiments, reflow may refer to a chemical process that includes cross-linking and/or rearrangement of chemical bonds within the material. Generally, reflowing the responsive layer may allow for changes to the topography of the surfaces of the material in order to decrease the surface energy of the responsive layer. As such, an undulating surface (before reflowing) may convert to a flatter surface after reflowing in order to reduce surface energy.

In an embodiment, responsive layers disclosed herein may comprise many different material systems. Generally, the material systems for the responsive layer comprise materials that can undergo a reflow in response to a treatment stimulus. In some embodiments, the responsive layer may be an organic material. For example, the responsive layer may comprise one or more of polymethyl methacrylate (PMMA), polystyrene (PS), Nylon 12, or polydimethylglutarimide (PMGI), parylene, or the like. More generally, responsive layers may comprise linear polymers with reflow behavior or polymer networks with reversible chemistry (e.g., reversible crosslinking or supramolecular crosslinking). In other embodiments, the responsive layer may be an inorganic material. For example, the responsive layer may comprise one or more of tin, bismuth, indium, or selenium. More generally, inorganic materials may be materials with reflow behavior at low temperatures (e.g., low melting temperatures). Other embodiments comprise polymers with disulfide bonds. For example, a polyurethane with disulfide bonds may be used in some embodiments.

In an embodiment, the responsive layer may be deposited with various different deposition processes. For example, dry deposition processes, such as chemical vapor deposition (CVD), plasma enhanced CVD (PE-CVD), atomic layer deposition (ALD), plasma enhanced ALD (PE-ALD), physical vapor deposition (PVD), or the like may be used in some embodiments. Dry processes may also comprise molecular layer deposition (MLD) processes.

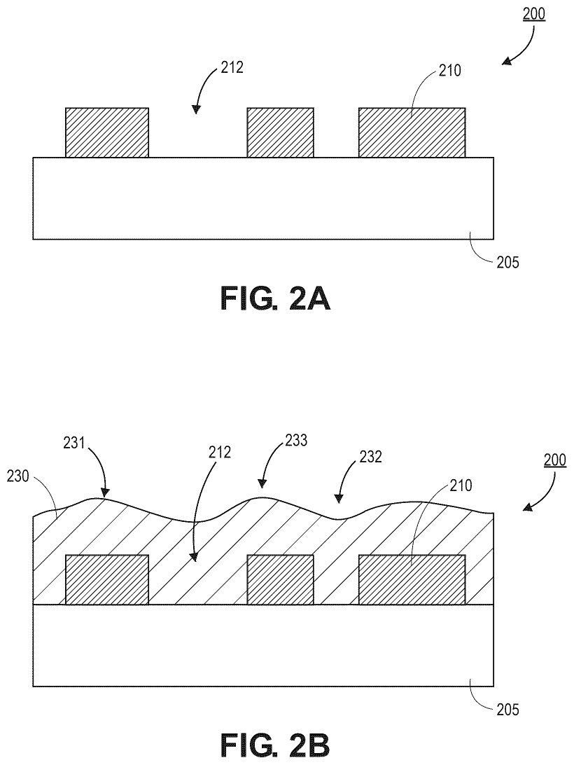

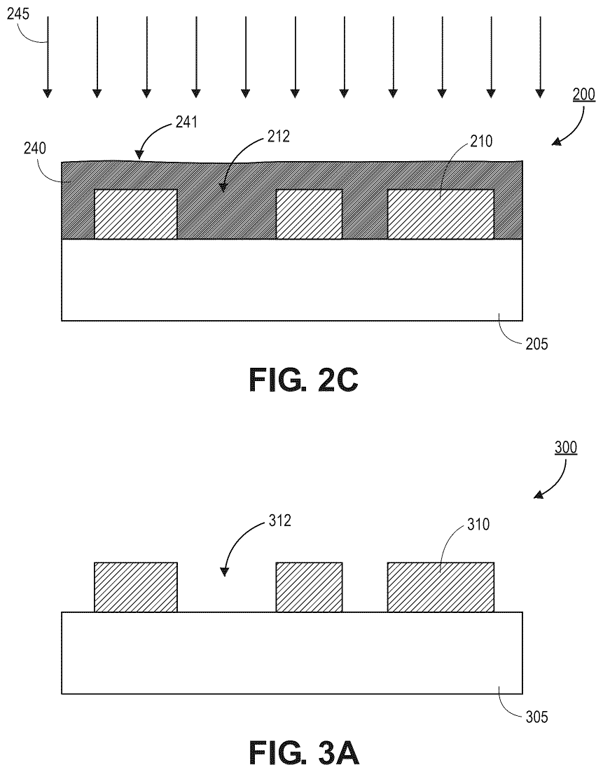

Referring now to FIG. 2A, a cross-sectional illustration of a device 200 is shown, in accordance with an embodiment. In an embodiment, the device 200 may comprise a substrate 205. The substrate 205 may be a semiconductor substrate, such as a silicon wafer. Though, other semiconductor materials, ceramics, glasses, or the like may also be used for the substrate 205. The substrate 205 may also have a form factor other than a form factor of a wafer.

In an embodiment, a patterned layer 210 is provided over the substrate. In an embodiment, the patterned layer 210 may comprise any material suitable for manufacturing semiconductor devices. For example, the patterned layer 210 may comprise a dielectric (e.g., a silicon oxide, a silicon nitride, etc.), a metal (e.g., copper, aluminum, tungsten, etc.), a semiconductor (e.g., silicon or the like), or the like. In an embodiment, the patterned layer 210 may comprise any type of pattern. For example, openings 212, gaps, recesses, and/or the like may be formed into and/or through the patterned layer 210. In an embodiment, the pattern may include a line/space pattern, pillars, holes, and/or the like. As shown in FIG. 2A, the openings 212 may have non-uniform dimensions in some embodiments. Though, in other embodiments the openings 212 may have uniform dimensions and/or a uniform pitch. In an embodiment, the patterned layer 210 may be patterned with any suitable patterning process. For example, a lithographic patterning process may be used in some embodiments.

Referring now to FIG. 2B, a cross-sectional illustration of the device 200 after a responsive layer 230 is deposited over the patterned layer 210 is shown, in accordance with an embodiment. In an embodiment, the responsive layer 230 may be deposited over the patterned layer 210 with a dry deposition process, such as a CVD process, a PECVD process, an ALD process, a PEALD process, or the like. The responsive layer 230 may substantially fill the openings 212 through the patterned layer 210, and the responsive layer 230 may cover top surfaces of the patterned layer 210.

However, as shown in FIG. 2B, the top surface 231 of the responsive layer 230 may be non-planar. For example, the top surface 231 may comprise peaks 233 and valleys 232. The valleys 232 may be substantially aligned with the openings 212 due to the conformal nature of the deposition of the responsive layer 230. Accordingly, the responsive layer 230 may comprise a material that is able to be reflowed in response to a treatment stimulus. For example, the stimulus may comprise a thermal stimulus, an electromagnetic radiation stimulus (e.g., light, UV light, etc.), a plasma treatment stimulus, a laser anneal stimulus, an ion implantation stimulus, or a chemical stimulus.

In an embodiment, the responsive layer 230 may comprise an organic material. For example, the responsive layer 230 may comprise linear polymers with reflow behavior, or polymer networks with reversible chemistry (e.g., reversible crosslinking or supramolecular crosslinking). For example, the responsive layer 230 may comprise one or more of PMMA, PS, Nylon 12, or PMGI. Such polymeric materials may be deposited with a CVD processes, such as a PECVD process, or ALD processes. Though, other deposition processes may also be used in some embodiments.

In another embodiment, the responsive layer 230 may comprise an inorganic material. For example, the responsive layer 230 may comprise one or more of tin, bismuth, indium, or selenium. More generally, inorganic materials may be materials with reflow behavior at low temperatures (e.g., low melting temperatures). Inorganic materials may be deposited with PVD processes, CVD processes (e.g., PECVD), or ALD processes. Though, other deposition processes may also be used in some embodiments.

Other embodiments comprise a responsive layer 230 that comprise polymers with disulfide bonds. For example, a polyurethane with disulfide bonds may be used in some embodiments. The use of disulfide bonds allows for the responsive layer 230 to reflow in a controllable manner in response to a given stimulus (e.g., heat or light). Such disulfide based polymers may be deposited with a molecular layer deposition (MLD) process. Though, other deposition processes may also be used in some embodiments.

In yet another embodiment, the responsive layer 230 may comprise a polymeric material with relatively long carbon chains with light crosslinking. In some instances, such a linear polymer chain may be deposited with a PECVD process that includes one or more of a low power, low temperature, and/or a pulsed plasma. In some embodiments, the polymer may be a low-k dielectric polymer material. A more detailed description of such linear chain polymers is described in greater detail herein.

In the case of a PECVD deposition process for the responsive layer 230, the pressure within the chamber during the deposition may be between approximately 1 Torr and approximately 100 Torr. Temperatures may range from between approximately 50 °C and approximately 200 °C. Bias power may be between approximately 50W and approximately 800W. The plasma may be a continuous wave or implemented with a pulsing process (e.g., with a duty cycle between approximately 10% and approximately 75%).

Embodiments described in greater detail herein may be enhanced by leveraging deposition techniques and precursor formulation chemistries in order to tailor the polymeric structure of the responsive layer. That is, any of the responsive layers described herein may utilize deposition techniques, chemistries, and/or treatments similar to those described below. In some embodiments, the use of one or more of low temperature, low power settings, and/or pulsing may lead to improved polymer networks within the responsive layer. More generally, this may lead to lightly cross-linked polymers with long linear CH₂ chains. The longer linear chains allow for reflow at lower temperatures in order to allow for surface energy reduction that leads to improved flatness of the responsive layer.

As noted herein, the responsive layer may be deposited with a dry deposition process. In a particular embodiment, the dry deposition process may be a PECVD process. The PECVD process may use any suitable plasma source, such as a capacitively coupled plasma (CCP), an inductively coupled plasma (ICP), a remote plasma source, or the like. When using a PECVD process, a low power plasma and low deposition temperature (e.g., less than 300 °C, less than 250 °C, or less than 100 °C) may be used. The use of such milder deposition conditions has shown (e.g., with a nuclear magnetic resonance (NMR) spectroscopy plot) to increase the distance between crosslinks as indicated by an increase in a peak with a chemical shift that is consistent with —CH₂— moieties. For example, an NMR spectroscopy plot of the responsive layer may show a higher mole fraction of sp³ aliphatic moieties than a mole fraction of sp² aliphatic moieties.

Additionally, the plasma may be pulsed in some embodiments. The pulsing may include an on-off cycle that is up to 1 second on and up to 1 second off, up to 5 seconds on and up to five seconds off, up to 10 seconds on and up to 10 second off, up to 30 seconds on and up to 30 seconds off, or any other duration. In some embodiments, the plasma on duration is equal to the plasma off duration for each cycle. In other embodiments, the plasma on duration is different than the plasma off duration. Pulsing the plasma in a PECVD deposition process may allow for better retention of the monomer structure in order to produce a linear polymer architecture.

In some embodiments, the precursor formulation used to deposit the responsive layer with such a deposition process may include one or more monomers that comprise carbon structures that contain one or more of hydrogen bonding, metal ligand interactions, van der waals interactions, hydrophobic effects, and/or dynamic covalent bonds (e.g., disulfides, oximes, imines, Michael-adducts, or diels-alder, etc.). For example, suitable monomers may include one or more of, N-[3-(dimethylamino)propyl]methacrylamide, 1-vinyl-2-pyrrolidinone, isobornyl methacrylate, norbornene, cyclohexyl methacrylate, styrene, vinylphenol, vinylpyridine, vinylimidazole, (2-Methylpropenyl)benzene, norbornenecarboxylic acid, propylene, propene, acetylene, octene, cyclooctene, cyclooctadiene, cycloalkene, cis-3-hexen-1-ol, isomers thereof, or any combination thereof. In some embodiments, the precursor formulation may further comprise a polymer inhibitor in addition to the monomer in the precursor formulation to enable delivery of the monomer to a chamber (e.g., the PECVD chamber) where polymerization occurs, while polymerization is prevented in the delivery vessel (e.g., an ampoule). That is, the precursor formulation may comprise a monomer mixture and an inhibitor in some embodiments. In an embodiment, the polymer inhibitor may be up to approximately 1.0 weight percent of the precursor formulation.

In an embodiment, the precursor formulation with the desired monomer is used to generate a polymeric species when deposited over the substrate within the chamber. In some embodiments, the polymeric species is linear. Though, embodiments may also include polymer structures that are a branched polymer, a catenated polymer, a comb-like polymer, a hyper-branched polymer, a cross-linked polymer, a dendrimer polymer, a dendron polymer, a block copolymer, a star polymer, a brush polymer, an AB₂ star polymer, a palm-tree ABₙ polymer, an H-shaped B₂AB₂ polymer, a dumbbell polymer, a ring block polymer, a star block ABₙ polymer, a coil-cycle-coil polymer, a star AₙBₙ polymer, a combination of any of the polymer structures, or the like. In some embodiments, a radical initiator (e.g., Ar, He, NH₃, H₂, or the like) may also be flown into the chamber with the precursor formulation in order to retain the monomer structure during deposition to minimize reaction of polymer chains after termination.

Referring now to FIG. 2C, a cross-sectional illustration of the device 200 after a treatment process is shown, in accordance with an embodiment. As shown a stimulus 245 is applied to the device 200. The stimulus 245 initiates a reflow of the responsive layer 230. While in a reflowable state, the responsive layer 230 is able to adjust free surfaces (e.g., top surface 241) in order to minimize surface energy. Accordingly, the peaks 233 and valleys 232 of the top surface 231 in FIG. 2B are reduced in the top surface 241 of the reflowed responsive layer 240 in FIG. 2C. The improved flatness of the top surface 241 of the reflowed responsive layer 240 may be used in order to provide improved patterning in overlying layers (not shown), and/or reduce manufacturing complexity for the device 200.

In an embodiment, the stimulus 245 may comprise a thermal stimulus. For example, the stimulus 245 may be applied by thermal lamps in an annealing chamber or the like. A hot-plate, a heated pedestal, a heated electrostatic chuck (ESC), or the like may also be used to apply thermal energy to the device 200. A laser may also apply the necessary thermal energy in some embodiments. The thermal energy may allow for the responsive layer 230 to reflow due to the material exceeding a glass transition temperature or a melting temperature. In some embodiments, the reflow of the responsive layer 230 is implemented at a low temperature that is compatible with the rest of the material stack of the device 200. For example, the reflow temperatures may be provided up to approximately 250 °C in some instances. Though, other embodiments may include reflow temperatures that are up to approximately 600 °C. In some embodiments, the thermal anneal may be implemented at a pressure between approximately 10 m Torr and approximately 100Torr.

In an embodiment, the stimulus 245 may also comprise a plasma treatment of the responsive layer 230. For example, the responsive layer 230 may be exposed to an HBr plasma. The plasma may be a direct plasma treatment or a remote plasma treatment. The plasma treatment of the responsive layer 230 may be implemented with or without a bias.

In an embodiment, the stimulus 245 may also comprise an electromagnetic radiation exposure (e.g., UV radiation, visible light, etc.). Such a stimulus 245 may be more controllable than other solutions. For example, a light source may be provided over the device 200, and the light source can provide a desired dose of the light in order to obtain the desired effect. Light exposure may allow for reflow through an increase in the flowability of the material, change in a chemical structure (e.g., reversible cross-linking, supramolecular cross-linking, etc.). In an embodiment, the stimulus 245 may be applied with a blanket exposure of the responsive layer 230. The stimulus 245 may be sourced from a broad spectrum lamp (or lamps) that produce electromagnetic radiation with wavelengths between approximately 190 nm and approximately 300 nm. The electromagnetic radiation stimulus 245 may be applied with one or more of an application of a bias source power, in an inert atmosphere, or at a temperature between 0 °C and 250 °C

In yet another embodiment, the stimulus 245 may comprise a laser annealing stimulus. In such an embodiment, the laser may have any suitable wavelength. In a particular embodiment, the laser has a wavelength of approximately 810 nm. The laser anneal may be implemented in a manner that locally raises a temperature of the responsive layer 230 to between approximately 300 °C and approximately 600 °C to allow for the desired reflow.

The laser may be scanned across the device 200 in some embodiments.

In another embodiment, the stimulus 245 may comprise an ion implantation. In an embodiment, the ions may be implanted into the responsive layer 230 at doses between 10¹⁴ atoms/cm² and 10¹⁶ atoms/cm². Implant angles may be between approximately 0°and approximately 85°. Suitable elements for implanting may include inert elements, such as one or more of xenon, argon, neon, helium, and/or the like.

In an embodiment, the stimulus 245 may also comprise a chemical stimulus 245. A chemical stimulus 245 may be applied through the injection of a chemical reagent into a chamber that triggers a reflow behavior. In one embodiment, the chemical stimulus may be applied through the use of a solvent vapor anneal process (SVA). An SVA process may include exposing the responsive layer 230 to one or more organic solvents. For example, some suitable organic solvents may include one or more of chlorobenzene, tetralin, N-methyl-2-pyrrolidinone (NMP), ethylene glycol, heptane, toluene, propylene glycol methyl ether acetate (PGMEA), propylene glycol methyl ether (PGME), or cyclohexanone. For example, temperatures during the application of the stimulus 245 may be between approximately room temperature (e.g., about 20 °C) and approximately 200 °C.

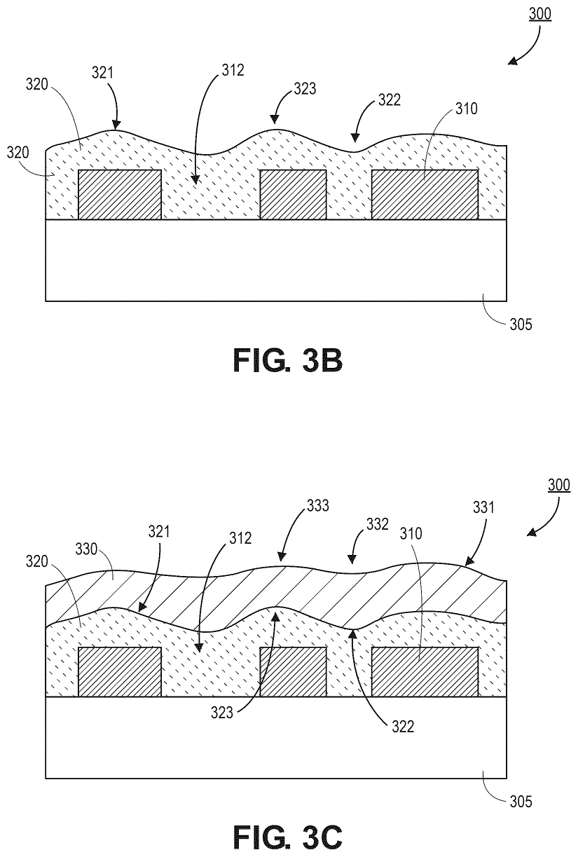

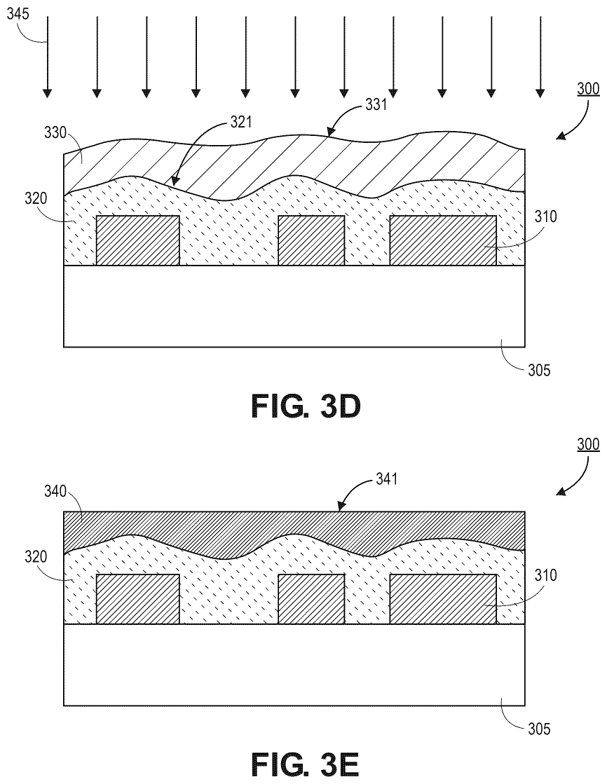

Referring now to FIGS. 3A-3E, a series of cross-sectional illustrations that depict a process for forming a device with a reflowed responsive layer that is deposited over a fill layer is shown, in accordance with an embodiment. As shown, the presence of the fill layer may allow for the responsive layer to be thinner. This may provide a smaller volume of material that needs to be reflowed, which may be beneficial for some applications.

Referring now to FIG. 3A, a cross-sectional illustration of a device 300 is shown, in accordance with an embodiment. In an embodiment, the device 300 may comprise a substrate 305. The substrate 305 may be a semiconductor substrate, such as a silicon wafer. Though, other semiconductor materials, ceramics, glasses, or the like may also be used for the substrate 305. The substrate 305 may also have a form factor other than a form factor of a wafer.

In an embodiment, a patterned layer 310 is provided over the substrate. In an embodiment, the patterned layer 310 may comprise any material suitable for manufacturing semiconductor devices. For example, the patterned layer 310 may comprise a dielectric (e.g., a silicon oxide, a silicon nitride, etc.), a metal (e.g., copper, aluminum, tungsten, etc.), a semiconductor (e.g., silicon or the like), or the like. In an embodiment, the patterned layer 310 may comprise any type of pattern. For example, openings 312, gaps, recesses, and/or the like may be formed into and/or through the patterned layer 310. In an embodiment, the pattern may include a line/space pattern, pillars, circular holes, and/or the like. As shown in FIG. 3A, the openings 312 may have non-uniform dimension and/or pitch in some embodiments. Though, in other embodiments the openings 312 may have uniform dimensions and/or a uniform pitch. In an embodiment, the patterned layer 310 may be patterned with any suitable patterning process. For example, a lithographic patterning process may be used in some embodiments.

Referring now to FIG. 3B, a cross-sectional illustration of the device 300 after a fill layer 320 is deposited over the patterned layer 310 is shown, in accordance with an embodiment. As shown, the fill layer 320 is deposited to a thickness that allows for the patterned layer 310 to be covered. The fill layer 320 may substantially fill the openings 312 through the patterned layer 310 and cover the top surface of the patterned layer 310.

A top surface 321 of the fill layer 320 may be non-planar. That is, the top surface 321 may comprise one or more peaks 323 and/or valleys 322. Due to the conformal nature of the deposition process used to deposit the fill layer 320, the valleys 322 may be aligned with the openings 312 through the patterned layer 310. In some instances, the deposition process may be a CVD process, a PECVD process or the like. The fill layer 320 may comprise a polymeric material, a dielectric layer (e.g., a silicon oxide or a silicon nitride), or the like.

Referring now to FIG. 3C, a cross-sectional illustration of the device 300 after a responsive layer 330 is deposited over the fill layer 320 is shown, in accordance with an embodiment. In an embodiment, the responsive layer 330 may be deposited over the fill layer 320 with a dry deposition process, such as a CVD process, a PECVD process, an ALD process, a PEALD process, or the like. The responsive layer 330 may substantially cover the top surface 321 of the fill layer 320.

However, as shown in FIG. 3C, the top surface 331 of the responsive layer 330 may be non-planar. For example, the top surface 331 may comprise peaks 333 and valleys 332. The valleys 332 may be substantially aligned with the openings 312 due to the conformal nature of the deposition of the responsive layer 330. Accordingly, the responsive layer 330 may comprise a material that is able to be reflowed in response to a treatment stimulus. For example, the stimulus may comprise one or more of a thermal stimulus, an electromagnetic radiation stimulus (e.g., light, UV light, etc.), a plasma treatment stimulus, a laser anneal stimulus, an ion implantation stimulus, or a chemical stimulus. In an embodiment, the responsive layer 330 may have a similar composition to the responsive layer 230 described in greater detail above, and/or the responsive layer 330 may be deposited onto the device 300 with processes similar to any of the responsive layer deposition processes described in greater detail herein.

Referring now to FIG. 3D, a cross-sectional illustration of the device 300 after a treatment stimulus 345 is applied to the responsive layer 330 is shown, in accordance with an embodiment. In an embodiment, the stimulus 345 may be similar to any of the stimuli described in greater detail herein. The stimulus 345 may result in the responsive layer 330 reflowing in order to reduce the surface energy of the top surface 331 of the responsive layer 330. For example, the stimulus 345 may comprise one or more of a thermal stimulus, an electromagnetic radiation stimulus (e.g., light, UV light, etc.), a plasma treatment stimulus, a laser anneal stimulus, an ion implantation stimulus, or a chemical stimulus.

Referring now to FIG. 3E, a cross-sectional illustration of the device 300 after the treatment is shown, in accordance with an embodiment. As shown, the treatment stimulus 345 has caused the responsive layer 330 to reflow to provide a modified responsive layer 340. The reflow of the modified responsive layer 340 results in an increase in the planarity of the top surface 341 of the modified responsive layer 340. The reduction in the magnitude of the peaks 333 and valleys 332 provides a flatter top surface 341. The flatter top surface 341 allows for simplified processing in subsequent operations. For example, when the overlying layer includes a resist material for EUV lithography, the thickness of the resist material can be more uniform. The improved uniformity is beneficial for EUV lithography since high-NA lenses have a poor depth of focus.

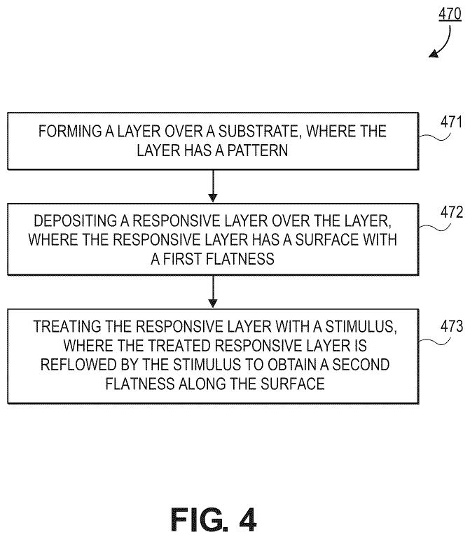

Referring now to FIG. 4, a flow diagram that describes a process 470 for reflowing a layer on a device is shown, in accordance with an embodiment. In an embodiment, the process 470 may be similar to the process described above with respect to FIGS. 2A-2C. In an embodiment, the process 470 may begin with operation 471, which comprises forming a layer over a substrate. In an embodiment, the layer may have a pattern. For example, the pattern may include a line/space pattern, a pattern of openings or holes, or the like. In an embodiment, the substrate may be a semiconductor substrate, such as a silicon wafer or the like. Though, the substrate may be similar to any of the substrates described in greater detail herein.

In an embodiment, the process 470 may continue with operation 472, which comprises depositing a responsive layer over the layer. In an embodiment, the responsive layer has a first flatness. For example, the responsive layer may at least partially conform to the pattern in the layer. As such, the top surface of the responsive layer may have peaks and valleys, where the valleys are located over openings through the layer. In an embodiment, the responsive layer may be deposited with a CVD process, a PECVD process, or any other suitable deposition process described in greater detail herein. In an embodiment, the responsive layer may comprise a material that is reflowable in response to a stimulus. The responsive layer may have a composition that is similar to any of the responsive layers described in greater detail herein.

In an embodiment, the process 470 may continue with operation 473, which comprises treating the responsive layer with a stimulus. In an embodiment, the treated responsive layer is reflowed by the stimulus to obtain a second flatness along the surface. In an embodiment, the second flatness is flatter than the first flatness. For example, the reflow may substantially remove peaks and valleys from the top surface of the responsive layer. In an embodiment, the stimulus may be any of the stimuli described in greater detail herein. For example, the stimulus may comprise one or more of a thermal stimulus, an electromagnetic radiation stimulus (e.g., light, UV light, etc.), a plasma treatment stimulus, a laser anneal stimulus, an ion implantation stimulus, or a chemical stimulus. In an embodiment, the reflow process may result in the responsive layer reflowing while the underlying layer remains substantially unchanged (e.g., the underlying layer does not reflow during the treatment).

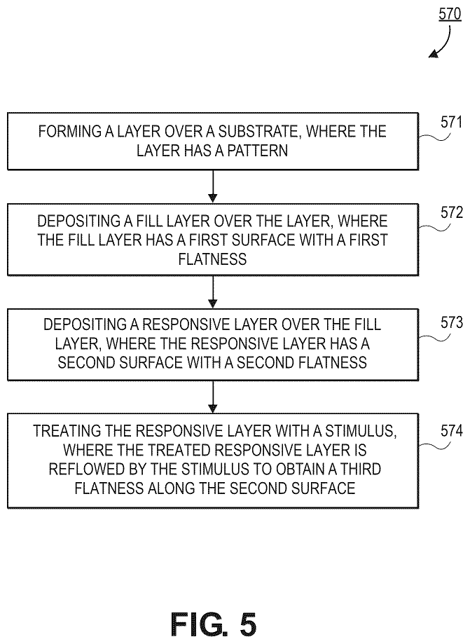

Referring now to FIG. 5, a flow diagram that described a process 570 for reflowing a layer on a device is shown, in accordance with an embodiment. In an embodiment, the process 570 may be similar to the process described above with respect to FIGS. 3A-3E. In an embodiment, the process 570 may begin with operation 571, which comprises forming a layer over a substrate. In an embodiment, the layer may have a pattern. For example, the pattern may include a line/space pattern, a pattern of openings or holes, or the like. In an embodiment, the substrate may be a semiconductor substrate, such as a silicon wafer or the like. Though, the substrate may be similar to any of the substrates described in greater detail herein.

In an embodiment, the process 570 may continue with operation 572, which comprises depositing a fill layer over the layer. In an embodiment, the fill layer has a first surface with a first flatness. In an embodiment, the fill layer may be deposited with a CVD process, a PECVD process, or the like. In an embodiment, the fill layer is at least partially conformal to the patterned layer. As such, the fill layer may comprise peaks and valleys.

In an embodiment, the process 570 may continue with operation 573, which comprises depositing a responsive layer over the fill layer. In an embodiment, the responsive layer has a second surface with a second flatness. For example, the responsive layer may at least partially conform to the pattern in the layer and non-planar surface of the fill layer. As such, the top surface of the responsive layer may also have peaks and valleys, where the valleys are located over openings through the layer. In an embodiment, the responsive layer may be deposited with a CVD process, a PECVD process, or any other suitable deposition process described in greater detail herein. In an embodiment, the responsive layer may comprise a material that is reflowable in response to a stimulus. The responsive layer may have a composition that is similar to any of the responsive layers described in greater detail herein. In some embodiments, the responsive layer and the fill layer may be deposited in the same chamber.

In an embodiment, the process 570 may continue with operation 574, which comprises treating the responsive layer with a stimulus. In an embodiment, the treated responsive layer is reflowed by the stimulus to obtain a second flatness along the surface. In an embodiment, the second flatness is flatter than the first flatness. For example, the reflow may substantially remove peaks and valleys from the top surface of the responsive layer. In an embodiment, the stimulus may be any of the stimuli described in greater detail herein. For example, the stimulus may comprise one or more of a thermal stimulus, an electromagnetic radiation stimulus (e.g., light, UV light, etc.), a plasma treatment stimulus, a laser anneal stimulus, an ion implantation stimulus, or a chemical stimulus. In an embodiment, the reflow process may result in the responsive layer reflowing while the underlying layer and the fill layer remain substantially unchanged (e.g., the underlying layer and the fill layer do not reflow during the treatment).

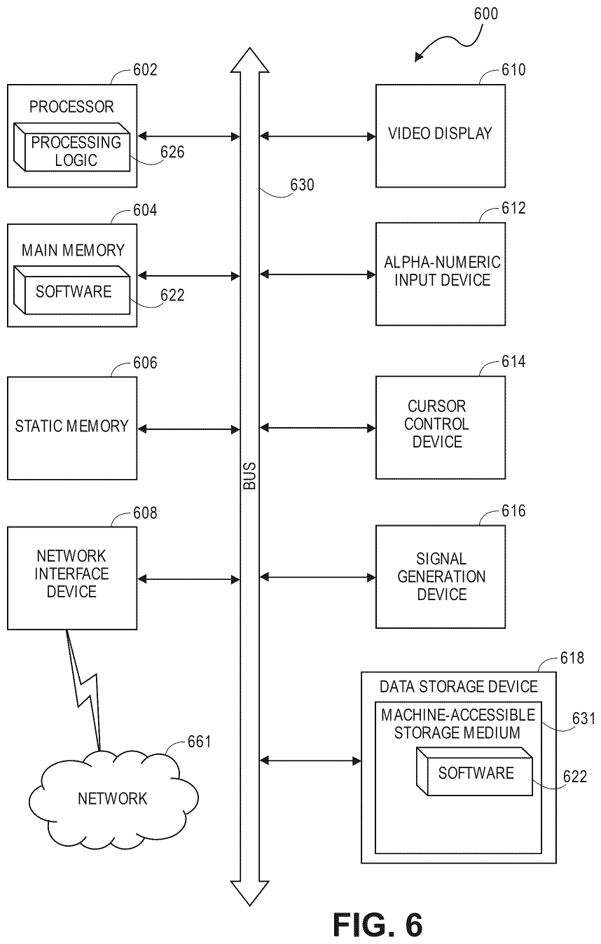

Referring now to FIG. 6, a block diagram of an exemplary computer system 600 of a processing tool is illustrated in accordance with an embodiment. In an embodiment, computer system 600 is coupled to and controls processing in the processing tool. Computer system 600 may be connected (e.g., networked) to other machines in a Local Area Network (LAN), an intranet, an extranet, or the Internet. Computer system 600 may operate in the capacity of a server or a client machine in a client-server network environment, or as a peer machine in a peer-to-peer (or distributed) network environment. Computer system 600 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 600, the term “machine” shall also be taken to include any collection of machines (e.g., computers) that individually or jointly execute a set (or multiple sets) of instructions to perform any one or more of the methodologies described herein.

Computer system 600 may include a computer program product, or software 622, having a non-transitory machine-readable medium having stored thereon instructions, which may be used to program computer system 600 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 600 includes a system processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

System processor 602 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 602 may also be one or more special-purpose processing devices such as an application specific integrated circuit (ASIC), a field programmable gate array (FPGA), a digital signal system processor (DSP), network system processor, or the like. System processor 602 is configured to execute the processing logic 626 for performing the operations described herein.

The computer system 600 may further include a system network interface device 608 for communicating with other devices or machines. The computer system 600 may also include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium 631 (or more specifically a computer-readable storage medium) on which is stored one or more sets of instructions (e.g., software 622) embodying any one or more of the methodologies or functions described herein. The software 622 may also reside, completely or at least partially, within the main memory 604 and/or within the system processor 602 during execution thereof by the computer system 600, the main memory 604 and the system processor 602 also constituting machine-readable storage media. The software 622 may further be transmitted or received over a network 661 via the system network interface device 608. In an embodiment, the network interface device 608 may operate using RF coupling, optical coupling, acoustic coupling, or inductive coupling.

While the machine-accessible storage medium 631 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method, comprising:
depositing a responsive layer over a patterned layer, wherein the responsive layer has a surface with a first flatness; and
treating the responsive layer with a stimulus, wherein the treated responsive layer is reflowed by the stimulus to obtain a second flatness along the surface that is flatter than the first flatness.

2. The method of claim 1, wherein the responsive layer is deposited over the patterned layer with a plasma enhanced chemical vapor deposition (PECVD) process.

3. The method of claim 2, wherein a precursor formulation for the PECVD process comprises monomers that comprise one or more of hydrogen bonding, metal ligand interactions, van der waals interactions, hydrophobic effects, and/or dynamic covalent bonds.

4. The method of claim 3, wherein the precursor formulation comprises one or more of N-[3-(dimethylamino)propyl]methacrylamide, 1-Vinyl-2-pyrrolidinone, isobornyl methacrylate, norbornene, cyclohexyl methacrylate, styrene, vinylphenol, vinylpyridine, vinylimidazole, (2-methylpropenyl)benzene, norbornenecarboxylic acid, propylene, propene, acetylene, octene, cyclooctene, cyclooctadiene, cycloalkene, cis-3-hexen-1-ol, or isomers thereof.

5. The method of claim 3, wherein the precursor formulation further comprises a polymer inhibitor.

6. The method of claim 1, wherein the stimulus comprises one or more of a thermal anneal, a plasma treatment, an ultraviolet radiation exposure, a laser anneal, an ion implantation, or a solvent vapor anneal.

7. The method of claim 1, wherein the responsive layer comprises a substantially linear polymeric architecture.

8. The method of claim 1, wherein the responsive layer comprises a low-k dielectric polymer.

9. The method of claim 1, wherein the responsive layer comprises a polymer structure that is a branched polymer, a catenated polymer, a comb-like polymer, a hyper-branched polymer, a cross-linked polymer, a dendrimer polymer, a dendron polymer, a block copolymer, a star polymer, a brush polymer, an AB₂ star polymer, a palm-tree ABₙ polymer, an H-shaped B₂AB₂ polymer, a dumbbell polymer, a ring block polymer, a star block ABₙ polymer, a coil-cycle-coil polymer, a star AₙBₙ polymer, or a combination of any of the polymer structures.

10. The method of claim 1, wherein a radical initiator is used during a deposition process used to deposit the responsive layer.

11. A method, comprising:
depositing a fill layer over a patterned layer, wherein the fill layer has a first surface with a first flatness;
depositing a responsive layer over the fill layer, wherein the responsive layer has a second surface with a second flatness; and
treating the responsive layer with a stimulus, wherein the treated responsive layer is reflowed by the stimulus to obtain a third flatness along the second surface that is flatter than the second flatness.

12. The method of claim 11, wherein the stimulus comprises one or more of a thermal anneal, a plasma treatment, an ultraviolet radiation exposure, a laser anneal, an ion implantation, or a solvent vapor anneal.

13. The method of claim 11, wherein the responsive layer is deposited with a chemical vapor deposition (CVD) process.

14. The method of claim 13, wherein the CVD process is a plasma enhanced CVD process.

15. The method of claim 13, wherein a precursor formulation for the CVD process comprises monomers that comprise one or more of hydrogen bonding, metal ligand interactions, van der waals interactions, hydrophobic effects, and/or dynamic covalent bonds.

16. The method of claim 11, wherein the fill layer and the responsive layer are deposited in the same chamber.

17. The method of claim 11, wherein the fill layer is thicker than the responsive layer.

18. A method, comprising:
patterning a first layer that is provided over a substrate, wherein the patterning forms an opening through the first layer;
depositing a second layer over the first layer with a plasma enhanced chemical vapor deposition (PECVD) process, wherein the second layer comprises a material that is reflowable in response to a stimulus; and
applying the stimulus to the second layer that results in the second layer being reflowed while the first layer remains substantially unchanged.

19. The method of claim 18, wherein the stimulus comprises one or more of a thermal anneal, a plasma treatment, an ultraviolet radiation exposure, a laser anneal, an ion implantation, or a solvent vapor anneal.

20. The method of claim 18, further comprising:
depositing a third layer over the first layer before the second layer is deposited, wherein the third layer and the second layer are deposited in the same chamber.
